(19) United States
(12) Patent Application Publication
(10) Pub. No.: US 2013/0175167 A1
(43) Pub. Date: Jul. 11, 2013

(54) FERROMAGNETIC SPUTTERING TARGET AND METHOD FOR MANUFACTURING SAME

(71) Applicants: Yuki Ikeda, Ibaraki (JP); Hideo Takami, Ibaraki (JP)

(72) Inventors: Yuki Ikeda, Ibaraki (JP); Hideo Takami, Ibaraki (JP)

(73) Assignee: JX NIPPON MINING & METALS CORPORATION, Tokyo (JP)

(21) Appl. No.: 13/824,146

(22) PCT Filed: Nov. 21, 2011
(86) PCT No.: PCT/JP2011/076774

§ 371 Date: Mar. 15, 2013

(30) Foreign Application Priority Data
Dec. 15, 2010 (JP) 2010-278798

(51) Int. Cl. C23C 14/34

(52) U.S. Cl. CPC C23C 14/3414
USPC 204/298.13; 419/19

(57) ABSTRACT

Provided is a ferromagnetic sputtering target having a composition containing 20 mol % or less of Cr, 5 to 30 mol % of Pt, 5 to 15 mol % of SiO₂, 0.05 to 0.60 mol % of Sn, with Co as a remainder thereof, wherein the Sn is contained in SiO₂ particles (B) dispersed in a metal substrate (A). The method yields a ferromagnetic sputtering target containing dispersed nonmagnetic particles. The target can prevent the abnormal electrical discharge of oxides which causes the generation of particles during sputtering.

### BACKGROUND

The present invention relates to a ferromagnetic sputtering target for use in the deposition of a magnetic thin film of a magnetic recording medium, and particularly of a magnetic recording layer of a hard disk adopting the perpendicular magnetic recording system, and to a nonmagnetic material particle-dispersed ferromagnetic sputtering target. The sputtering target can prevent the abnormal electrical discharge of oxides which causes the generation of particles during sputtering. The present invention also provides the method for manufacturing same.

There are various types of sputtering devices, but a magnetron sputtering device comprising a DC power source is broadly used in light of its high productivity for the deposition of the foregoing magnetic recording film. This sputtering method causes a positive electrode substrate and a negative electrode target to face each other, and generates an electric field by applying high voltage between the substrate and the target under an inert gas atmosphere.

Here, the sputtering method employs a fundamental principle where inert gas is ionized, plasma composed of electrons and cations is formed, and the cations in the plasma collide with the target (negative electrode) surface so as to sputter the atoms configuring the target. The discharged atoms adhere to the opposing substrate surface, wherein the film is formed. As a result of performing the sequential process described above, the material configuring the target is deposited on the substrate.

Meanwhile, upon examining the development of magnetic materials, in the field of magnetic recording as represented with hard disk drives, a material based on Co, Fe or Ni as ferromagnetic metals is used as the material of the magnetic thin film which is used for the recording. For example, Co—Cr-based or Co—Cr—Pt-based ferromagnetic alloys with Co as its main component are used for the recording layer of hard disks adopting the longitudinal magnetic recording system.

Moreover, composite materials of Co—Cr—Pt-based ferromagnetic alloys with Co as its main component and nonmagnetic inorganic material are often used for the recording layer of hard disks adopting the perpendicular magnetic recording system which was recently put into practical application.

A magnetic thin film of a magnetic recording medium such as a hard disk is often produced by sputtering a ferromagnetic sputtering target having the foregoing materials as its components in light of its high productivity.

As a method of manufacturing this kind of ferromagnetic sputtering target, the melting method or powder metallurgy may be considered. It is not necessarily appropriate to suggest which method is better since it will depend on the demanded characteristics, but a sputtering target made of ferromagnetic alloys and nonmagnetic inorganic particles used for the recording layer of hard disks adopting the perpendicular magnetic recording system is generally manufactured with powder metallurgy. This is because the inorganic particles need to be uniformly dispersed within the alloy substrate, and this is difficult to achieve with the melting method.

For example, proposed is a method of performing mechanical alloying to an alloy powder having an alloy phase prepared by the rapid solidification method and a powder configuring the ceramic phase, causing the powder configuring the ceramic phase to be uniformly dispersed in the alloy powder, and performing hot press thereto in order to obtain a sputtering target for use in a magnetic recording medium (Patent Document 1).

The target structure in the foregoing case appears to be such that the base metal is bonded in a milt (cod fish sperm) shape and surrounded with SiO₂ (ceramic) (FIG. 2 of Patent Document 1) or dispersed in a thin string shape (FIG. 3 of Patent Document 1). While it is blurred in the other diagrams, the target structure in such other diagrams is also assumed to be of the same structure. This kind of structure entails the problems described later, and it cannot be said that this kind of structure is a preferred sputtering target for a magnetic recording medium. Note that the spherical substance shown in FIG. 4 of Patent Document 1 is mechanical alloying powder, and is not a structure of the target.

Moreover, without having to use the alloy powder prepared by the rapid solidification method, it is also possible to produce a ferromagnetic sputtering target by preparing commercially available raw material powders for the respective components configuring the target, weighing these raw material powders to achieve the intended composition, mixing the raw material powders with a known method such as a ball mill or the like, and molding and sintering the mixed powder via hot press.

For example, proposed is a method of obtaining a sputtering target for a magnetic recording medium including the steps of mixing Co powder, Cr powder, TiO₂ powder and SiO₂ powder, mixing the obtained mixed powder and Co spherical powder with a planetary-screw mixer, and molding the mixed powder with hot pressing (Patent Document 2).

With the target structure in the foregoing case, a spherical phase (B) can be observed in a metallic substrate phase (A) in which inorganic material particles are uniformly dispersed (FIG. 1 of Patent Document 2).

While this kind of structure is favorable from the view of improving pass-through flux, it is not necessarily favorable as a sputtering target for a magnetic recording medium from the view of inhibiting the generation of particles during sputtering.

In addition, proposed is a method of obtaining a sputtering target for forming a thin film for use in a magnetic recording medium including the steps of mixing Co—Cr binary system alloy powder, Pt powder and SiO₂ powder, and hot pressing the obtained mixed powder (Patent Document 3).

While the target structure in the foregoing structure is not shown in the drawings, it is described that a Pt phase, a SiO₂ phase and a Co—Cr binary system alloy phase are visible, and that a diffusion layer can be observed around the Co—Cr binary system alloy layer. This kind of structure is also not necessarily favorable as a sputtering target for a magnetic recording medium.

In addition to the above, several proposals have been made in view of the development of magnetic materials. For example, Patent Document 4 proposes a vertical magnetic recording medium having a SiC and SiOx (x: 1 to 2). Moreover, Patent Document 5 describes a magnetic material target containing Co, Pt, first metal oxide, second metal oxide, and third metal oxide.

Moreover, Patent Document 6 proposes a sputtering target made of a matrix phase of Co and Pt, and a metal oxide phase, and proposes improving the deposition efficiency by inhibiting the crystal grain growth and obtaining a low magnetic permeability, high density target.

Moreover, Patent Document 7 describes a nonmagnetic material particle-dispersed ferromagnetic sputtering target having, as the ferromagnetic material, Co and Fe as its main components, and in which the shape of the nonmagnetic material is specified based on a material selected from oxide, nitride, carbide, and silicide.

Moreover, Patent Document 8 describes a nonmagnetic material particle-dispersed ferromagnetic sputtering target in which nonmagnetic material particles made of oxide are dispersed in a ferromagnetic material of Co—Cr alloy, and describes a sputtering target in which the particle size thereof is prescribed in detail. Moreover, Patent Document 9 describes a magnetic film having a granular structure.

As described above, with a nonmagnetic material particle-dispersed ferromagnetic sputtering target made of Co—Cr—Pt oxides or the like, the use of SiO₂ or Cr₂O₃, TiO₂ as oxides has been proposed, and the proposal of specifying the shape of oxide has also been made. Nevertheless, since these oxides are insulators, they cause abnormal discharge. In addition, there is a problem in that this abnormal discharge causes the generation of particles during sputtering.

While the probability of abnormal discharge has been previously reduced by reducing the particle size of oxides, pursuant to the increase in recording density of the magnetic recording medium, the tolerable particle level is becoming severe. Thus, the current circumstances are demanding even further improvement.

[Patent Document 1] Japanese Unexamined Patent Application Publication No. H10-88333
[Patent Document 2] Japanese Patent Application No. 2010-011326
[Patent Document 3] Japanese Unexamined Patent Application Publication No. 2009-001860
[Patent Document 4] Japanese Unexamined Patent Application Publication No. 2006-127621
[Patent Document 5] Japanese Unexamined Patent Application Publication No. 2007-4957
[Patent Document 6] Japanese Unexamined Patent Application Publication No. 2009-102707
[Patent Document 7] Domestic Re-publication of PCT International Application No. WO2007/080781
[Patent Document 8] International Publication No. WO2009/119812A1
[Patent Document 9] Japanese Unexamined Patent Application Publication No. 2001-76329

### SUMMARY OF THE INVENTION

### Problems To Be Solved By the Invention

Generally, with a nonmagnetic material particle-dispersed ferromagnetic sputtering target made of Co—Cr—Pt oxides or the like, since oxides such as SiO₂, Cr₂O₃, TiO₂ contained therein are insulators, they cause abnormal discharge. In addition, there is a problem in that this abnormal discharge causes the generation of particles during sputtering.

In light of the problems, an object of this invention is to inhibit the abnormal discharge of oxides and reduce the generation of particles during sputtering which cause abnormal discharge. While the probability of abnormal discharge has been previously reduced by reducing the particle size of oxides, pursuant to the increase in recording density of the magnetic recording medium, the tolerable particle level is becoming severe. Thus, the present invention aims to provide a more improved nonmagnetic material particle-dispersed ferromagnetic sputtering target.

### Solution To the Problems

In order to achieve the foregoing object, as a result of intense study, the present inventors discovered that it is possible to obtain a target with low generation of particles and which does not generate an abnormal discharge caused by oxides during sputtering by adjusting the composition and structure of the target.

Based on the foregoing discovery, the present invention provides:
1) A ferromagnetic sputtering target having a composition containing 20 mol % or less of Cr, 5 to 30 mol % of Pt, 5 to 15 mol % of SiO₂, 0.05 to 0.60 mol % of Sn, and Co as a remainder thereof, wherein the Sn is contained in SiO₂ particles (B) dispersed in a metal substrate (A).

The present invention additionally provides:
2) The ferromagnetic sputtering target according to 1) above, wherein, in addition to the SiO₂, one or more types of oxides selected from TiO₂, Ti₂O₃, Cr₂O₃, Ta₂O₅, Ti₅O₉, B₂O₃, CoO, and Co₃O₄ are contained in an amount of 5 to 15 mol %, the oxides are dispersed in the metal substrate (A), and the Sn is contained in the oxides.

The present invention additionally provides:
3) The ferromagnetic sputtering target according to 1) or 2) above, wherein one or more types of elements selected from Ru, B, and Ta are contained in an amount of 0.5 to 10 mol %.
4) The ferromagnetic sputtering target according to any one of 1) to 3) above, wherein a relative density is 97% or higher.

The present invention additionally provides:
5) A method of producing a ferromagnetic sputtering target, wherein SiO₂ powder and SnO₂ powder or Sn powder are blended and mixed in advance to achieve a composition of 20 mol % or less of Cr, 5 to 30 mol % of Pt, 5 to 15 mol % of SiO₂, 0.05 to 0.60 mol % of Sn, and Co as a remainder thereof, Co powder, Cr powder, and Pt powder similarly blended to achieve the composition are mixed with the mixed powder, and the obtained mixed powder is hot pressed to obtain a sintered compact having a structure where SiO₂ particles (B) are dispersed in a sintered metal substrate (A), and the Sn is contained in the dispersed SiO₂ particles (B).

The present invention additionally provides:
6) The method of producing a ferromagnetic sputtering target according to 5) above, wherein, in addition to the SiO₂, one or more types of oxides selected from TiO₂, Ti₂O₃, Cr₂O₃, Ta₂O₅, Ti₅O₉, B₂O₃, CoO, and Co₃O₄ are added in an amount of 5 to 15 mol % to obtain a sintered compact having a structure in which the oxides are dispersed in the sintered metal substrate (A), and the Sn is contained in the oxides.

The present invention additionally provides:
7) The method of producing a ferromagnetic sputtering target according to 5) or 6) above, wherein one or more types of elements selected from Ru, B, and Ta are added in an amount of 0.5 to 10 mol %, and sintering is subsequently performed.

### Effect of the Invention

The nonmagnetic material particle-dispersed ferromagnetic sputtering target of the present invention adjusted as described above is a target with low generation of particles and which does not generate an abnormal discharge caused by oxides during sputtering.

In addition, the present invention yields superior effects of being able to inhibit the abnormal discharge of oxides, reduce the generation of particles during sputtering which cause abnormal discharge, and realize a cost improvement effect based on yield improvement.

### BEST MODE FOR CARRYING OUT THE INVENTION

The main components configuring the ferromagnetic sputtering target of the present invention are metals of a composition containing 20 mol % or less of Cr, 5 to 30 mol % of Pt, 5 to 15 mol % of SiO₂, 0.05 to 0.60 mol % of Sn, and Co as a remainder thereof. The foregoing Cr amount, Pt amount, and Co amount are respectively effective amounts for the present invention to maintain the characteristics as a ferromagnetic sputtering target; that is, as a ferromagnetic material thin film.

Note that, needless to say, Cr is added as an essential component, and the additive amount excludes 0 mol %. In other words, Cr is contained at least in an amount that is an analyzable lower limit or more. If the Cr amount is 20 mol % or less, this is effective also in cases of adding trace amounts. The present invention covers all of the above. The foregoing are components that are required as a magnetic recording medium; and, while the blending ratio can be variously adjusted to be within the foregoing range, all cases enable the present invention to maintain characteristics as an effective magnetic recording medium.

The ferromagnetic sputtering target can be prepared by blending and mixing SiO₂ powder and SnO₂ powder or Sn powder in advance to achieve the foregoing composition, additionally mixing Co powder, Cr powder, and Pt powder similarly blended to achieve the composition with the foregoing mixed powder, and hot pressing the obtained mixed powder.

What is important in the present invention is that obtained is a sintered compact in which SiO₂ particles (B) are dispersed in the sintered metal substrate (A), and the Sn is contained in the dispersed SiO₂ particles (B).

Generally, when SiO₂ is added to a Co—Cr—Pt-based ferromagnetic body, SiO₂ will exist as particles in the sintered compact sputtering target. However, since SiO₂ is an insulator, SiO₂ will cause the inducement of arcing, namely abnormal discharge in cases of existing independently. Thus, in the present invention, Sn, which has electrical conductivity relative to SiO₂, is introduced to lower the electrical resistance, and thereby inhibit the abnormal discharge caused by oxides.

The reason why the SiO₂ amount is set to be 5 mol % or higher and 15 mol % or less is because this is the standard range for obtaining favorable magnetic property.

The addition of Sn may be independent or combined, and effects are yielded in either case. Note that an independent addition means the addition as SnO₂ powder or Sn powder, and a combined addition means the addition as mixed powder of SiO₂ powder and SnO₂ powder or SiO₂ powder and Sn powder. The effective additive amount thereof is within the range of 0.05 to 0.60 mol %. If the additive amount is less than the lower limit, the effect of providing conductivity to SiO₂ will be lost. Contrarily, if the additive amount exceeds the upper limit, the magnetic property of the sputtered film will be affected, and it may not be possible to obtain the intended characteristics.

In addition to the SiO₂, one or more types of oxides selected from TiO₂, Ti₂O₃, Cr₂O₃, Ta₂O₅, Ti₅O₉, B₂O₃, CoO, and Co₃O₄ may be contained in an amount of 5 to 15 mol %

These oxides are dispersed in the metal substrate (A), and, as with the SiO₂, Sn may also be contained in these oxides. These oxides may be arbitrarily selected and added according to the type of ferromagnetic film that is required. The additive amount is the effective amount for exhibiting the effect of such addition.

In addition, with the ferromagnetic sputtering target of the present invention, one or more types of elements selected from Ru, B, and Ta may be contained in an amount of 0.5 to 10 mol %. These are elements that are added as needed to improve the characteristics as a magnetic recording medium. The additive amount is the effective amount for exhibiting the effect of such addition.

With the ferromagnetic sputtering target of the present invention, the relative density is desirably 97% or higher. Generally, it is known that a target having higher density can reduce the amount of particles that is generated during sputtering.

The same applies in the present invention; the higher the density of the ferromagnetic sputtering target, the better it is. The present invention can achieve a relative density of 97% or higher.

In the present invention, the term “relative density” is a value obtained by dividing the measured density of the target by the calculated density (also known as the theoretical density). The term “calculated density” is a density that is obtained on the assumption that the constituents of the target coexist without mutually diffusing or reaction, and is calculated according to the following formula.

Calculated density=Σ(molecular weight of constituents×molar ratio of constituents)/(molecular weight of constituents×molar ratio of constituents/literature value density of constituents) Formula:

Here, Σ means to acquire the sum regarding all constituents of the target.

The target adjusted as described above becomes a target with low generation of particles and which does not generate arcing, namely abnormal discharge caused by oxides during sputtering.

Also as described above, since conductivity is given to the SiO₂ particles based on the addition of Sn, effects are yielded in that the generation of abnormal discharge can be prevented, and the amount of particles generated which cause the production yield to deteriorate, can be reduced.

The ferromagnetic sputtering target of the present invention can be manufactured with powder metallurgy. Here, powders of the respective metal elements and, as needed, powders of the additive metal elements are foremost prepared. Desirably, the maximum particle size of these powders is 20 μm or less. Moreover, the alloy powders of these metals may also be prepared in substitute for the powders of the respective metal elements, and, desirably, the maximum particle size is also 20 μm or less in the foregoing case.

Meanwhile, if the particle size is too small, there is a problem in that oxidation is promoted and the component composition will not fall within the intended range. Thus, desirably, the particle size is 0.1 μm or more.

Subsequently, these metal powders and alloy powders are weighed to obtain the intended composition, and mixed and pulverized with well-known methods by using a ball mill or the like. Upon using oxide powders other than SiO₂, they should be added to the metal powders and alloy powders at this stage.

The maximum particle size of oxide powders other than SiO₂ is desirably 5 μm or less. Meanwhile, if the particle size is too small, the powders become clumped together, and the particle size is therefore desirably 0.1 μm or more.

Moreover, as the mixer, a planetary-screw mixer or a planetary-screw agitator/mixer is preferably used. In addition, mixing is preferably performed in an inert gas atmosphere or a vacuum in consideration of the problem of oxidation in the mixing process.

In addition, after mixing and blending SiO₂ powder and SnO₂ powder or Sn powder in advance to achieve a composition of 20 mol % or less of Cr, 5 to 30 mol % of Pt, 5 to 15 mol % of SiO₂, 0.05 to 0.60 mol % of Sn, and Co as a remainder thereof, it is effective to mix Co powder, Cr powder, and Pt powder similarly blended to achieve the composition with the foregoing mixed powder.

By molding and sintering the powder obtained as described, using a vacuum hot press device and cutting it into an intended shape, it is possible to produce the ferromagnetic sputtering target of the present invention.

In the sintered compact target, the added Sn or SnO₂ is contained in the SiO₂ particles that were preferentially dispersed in the metal substrate phase, and the electrical resistance of the SiO₂ particles is thereby reduced. The electrical resistance after the addition can achieve 5.5×10¹⁶Ω·cm or less.

The electrical resistance when Sn or SnO₂ is not added will exceed 5.5×10¹⁶Ω·cm, and since Sn or SnO₂ would function as an insulating material, it caused the inducement of abnormal discharge. However, the present invention can eliminate this phenomenon and considerably reduce the generation of arcing, namely abnormal discharge.

Moreover, the molding and sintering processes are not limited to the hot press method, and a plasma discharge sintering method or a hot isostatic sintering method may also be used. The holding temperature in the sintering process is preferably set to the lowest temperature within the temperature range in which the target can be sufficiently densified. Although this will depend on the composition of the target, in many cases the temperature range that is adopted is 900 to 1200° C.

While a Co—Cr—Pt-based ferromagnetic body was explained above, a Co—Pt-based ferromagnetic body can also achieve similar results based on similar component composition and production method.

### EXAMPLES

The present invention is now explained in detail with reference to the Examples and Comparative Examples. Note that these Examples are merely illustrative, and the present invention shall in no way be limited thereby. In other words, various modifications and other embodiments are covered by the present invention, and the present invention is limited only by the scope of its claims.

### Example 1

In Example 1, SiO₂ powder having an average grain size of 1 μm and SnO₂ powder having an average grain size of 1 μm were prepared in advance as raw material powders and weighed to achieve 95 wt % of SiO₂ powder and 5 wt % of SnO₂, and mixed for 1 hour using a ball mill to prepare a SiO₂—SnO₂ mixed powder. This mixed powder and Co powder having an average grain size of 3 μm, Cr powder having an average grain size of 5 μm, and Pt powder having an average grain size of 3 μm were weighed at a weight percentage of 70.56 wt % of Co powder, 9.59 wt % of Cr powder, 14.99 wt % of Pt powder, and 4.86 wt % of SiO₂—SnO₂ mixed powder to achieve a target composition of 78 Co-12 Cr-5 Pt-5 SiO₂-0.1 SnO₂ (mol %).

Subsequently, the Co powder, Cr powder, Pt powder and SiO₂—SnO₂ mixed powder were placed in a ball mill pot with a capacity of 10 liters together with zirconia balls as the grinding medium, and rotated and mixed for 20 hours.

This mixed powder was filled in a carbon mold, and hot pressed in a vacuum atmosphere under the following conditions; namely, temperature of 1100° C., holding time of 3 hours, and pressure of 30 MPa to obtain a sintered compact. This was further cut with a lathe to obtain a disk-shaped target having a diameter of 180 mm and thickness of 7 mm.

As a result of sputtering this target, the number of particles that were generated in a normal state was 2.8 particles. And, the relative density was 98.5%, and a high density target having a relative density exceeding 97% was obtained.

Moreover, in order to measure the electrical resistance of the mixed powder, 95 wt % of SiO₂ powder having an average grain size of 1 μm and 5 wt % of SnO₂ powder having an average grain size of 1 μm were placed in a ball mill pot with a capacity of 10 liters, and rotated and mixed for 1 hour. The obtained mixed powder was filled in a carbon mold, and hot pressed in a vacuum atmosphere under the following conditions; namely, temperature of 1100° C., holding time of 3 hours, and pressure of 30 MPa to obtain a sintered compact. The electrical resistance in this case was measured, and the result was 4.0×10¹⁶Ω·cm.

### Comparative Example 1

In Comparative Example 1, Co powder having an average grain size of 3 pm, Cr powder having an average grain size of 5 μm, Pt powder having an average grain size of 1 μm, and SiO₂ powder average grain size of 1 μm were prepared as the raw material powders. These powders were weighed at a weight percentage of 70.76 wt % of Co powder, 9.60 wt % of Cr powder, 15.01 wt % of Pt powder, and 4.62 Wt % of SiO₂ powder to achieve a target composition of 78 Co-12 Cr-5 Pt-5 SiO₂ (mol %).

These powders were placed in a ball mill pot with a capacity of 10 liters together with zirconia balls as the grinding medium, and rotated and mixed for 20 hours.

Subsequently, the foregoing mixed powder was filled in a carbon mold, and hot pressed in a vacuum atmosphere under the following conditions; namely, temperature of 1100° C., holding time of 2 hours, and pressure of 30 MPa to obtain a sintered compact. This was further cut with a lathe to obtain a disk-shaped target having a diameter of 180 mm and thickness of 7 mm.

As a result of sputtering this target, the number of particles generated in a normal state increased to 6.7 particles. And, the relative density was 98.0%, and a high density target having a relative density exceeding 97% was obtained.

Note that the foregoing Example explained a case of adding SiO₂, but similar effects can be obtained as in the case of adding SiO₂ even upon adding one or more types of oxides selected from TiO₂, Ti₂O₃, Cr₂O₃, Ta₂O₅, Ti₅O₉, B₂O₃, CoO, and Co₃O₄. Moreover, upon containing one or more elements selected from Ru, B, and Ta in an amount of 0.5 to 10 mol %, it has been confirmed that the characteristics as a magnetic recording medium can be further improved.

### INDUSTRIAL APPLICABILITY

By adjusting the structure of the ferromagnetic sputtering target, the present invention enables the reduction in the generation of particles without any generation of abnormal discharge caused by oxides during sputtering. Accordingly, if the target of the present invention is used, a stable discharge can be obtained when performing sputtering with a magnetron sputtering device. Further, the present invention is effective as a ferromagnetic sputtering target for use in forming a magnetic body thin film of a magnetic recording medium, and particularly for forming a hard disk drive recording layer, since this invention yields superior effects of being able to inhibit the abnormal discharge of oxides, reduce the generation of particles during sputtering which cause abnormal discharge, and realize a cost improvement effect based on improvement of production yield.

1. A ferromagnetic sputtering target having a composition containing 20 mol % or less of Cr, 5 to 30 mol % of Pt, 5 to 15 mol % of SiO₂, 0.05 to 0.60 mol % of Sn, and Co as a remainder thereof, wherein the Sn is contained in Sio₂ particles (B) dispersed in a metal substrate (A).

2. The ferromagnetic sputtering target according to claim 1, wherein, in addition to the SiO₂, one or more types of oxides selected from TiO₂, Ti₂O₃, Cr₂O₃, Ta₂O₅, Ti₅O₉, B₂O₃, CoO, and Co₃O₄ are contained in an amount of 5 to 15 mol %, the oxides are dispersed in the metal substrate (A), and the Sn is contained in the oxides.

3. The ferromagnetic sputtering target according to claim 2, wherein one or more types of elements selected from Ru, B, and Ta are contained in an amount of 0.5 to 10 mol %.

4. The ferromagnetic sputtering target according to claim 3, wherein a relative density is 97% or higher.

5. A method of producing a ferromagnetic sputtering target, wherein SiO₂ powder and SnO₂ powder or Sn powder are blended and mixed in advance to achieve a composition of 20 mol % or less of Cr, 5 to 30 mol % of Pt, 5 to 15 mol % of SiO₂, 0.05 to 0.60 mol % of Sn, and Co as a remainder thereof, Co powder, Cr powder, and Pt powder similarly blended to achieve the composition are mixed with the mixed powder, and the obtained mixed powder is hot pressed to obtain a sintered compact having a structure where SiO₂ particles (B) are dispersed in a sintered metal substrate (A), and the Sn is contained in the dispersed SiO₂ particles (B).

6. The method of producing a ferromagnetic sputtering target according to claim 5, wherein, in addition to the SiO₂, one or more types of oxides selected from TiO₂, Ti₂O₃, Cr₂O₃, Ta₂O₅, Ti₅O₉, B₂O₃, CoO, and Co₃O₄ are added in an amount of 5 to 15 mol % to obtain a sintered compact having a structure in which the oxides are dispersed in the sintered metal substrate (A), and the Sn is contained in the oxides.

7. The method of producing a ferromagnetic sputtering target according to claim 6, wherein one or more types of elements selected from Ru, B, and Ta are added in an amount of 0.5 to 10 mol %, and sintering is subsequently performed.

8. The method of producing a ferromagnetic sputtering target according to claim 5, wherein one or more types of elements selected from Ru, B, and Ta are added in an amount of 0.5 to 10 mol %, and sintering is subsequently performed.

9. The ferromagnetic sputtering target according to claim 1, wherein one or more types of elements selected from Ru, B, and Ta are contained in an amount of 0.5 to 10 mol %.

10. The ferromagnetic sputtering target according to claim 9, wherein a relative density is 97% or higher.

11. The ferromagnetic sputtering target according to claim 1, wherein a relative density is 97% or higher.
